(19) United States
(12) Patent Application Publication
(10) Pub. No.: US 2026/0122776 A1
(43) Pub. Date: Apr. 30, 2026

(54) SEMICONDUCTOR PACKAGE INCLUDING OPTICAL PRINTED CIRCUIT BOARD

(71) Applicant: Samsung Electronics Co., Ltd., Suwon-si (KR)

(72) Inventor: Hyejin KIM, Suwon-si (KR)

(73) Assignee: Samsung Electronics Co., Ltd., Suwon-si (KR)

(21) Appl. No.: 19/232,206

(22) Filed: Jun. 9, 2025

(30) Foreign Application Priority Data
Oct. 30, 2024 (KR) 10-2024-0151510

(51) Int. Cl. H05K 1/02; G02B 6/12; G02B 6/122; G02B 6/125

(52) U.S. Cl. CPC H05K 1/0274; G02B 6/12004; G02B 6/1228; G02B 6/125; H05K 2201/09827; H05K 2201/09985; H05K 2201/10121

(57) ABSTRACT

A semiconductor package includes an optical printed circuit board (PCB) and an integrated circuit device on the optical PCB. The optical PCB includes a base layer, at least one photoimageable dielectric (PID) layer on the base layer, a horizontal optical waveguide extending in a horizontal direction in the at least one PID layer, a first via optical waveguide on a first side of the horizontal optical waveguide, in optical communication with the horizontal optical waveguide, and extending perpendicular to the at least one PID layer, and a second via optical waveguide on a second side of the horizontal optical waveguide, in optical communication with the horizontal optical waveguide, and extending perpendicular to the at least one PID layer.

### CROSS-REFERENCE TO RELATED APPLICATION

This application is based on and claims priority under 35 U.S.C. § 119 to Korean Patent Application No. 10-2024-0151510, filed on Oct. 30, 2024, in the Korean Intellectual Property Office, the disclosure of which is incorporated by reference herein in its entirety.

### BACKGROUND

The present disclosure relates to a semiconductor package, and more particularly, to a semiconductor package including an optical printed circuit board (PCB).

PCB technology using copper-based electrical wiring is reaching its limits due to increased data speeds and high capacity in electronic components. Accordingly, optical PCBs including optical waveguides are attracting attention as technologies capable of overcoming problems of conventional copper-based electrical wiring. There is a need to improve optical transmission characteristics of Optical PCBs by reducing optical loss in optical waveguides.

### SUMMARY

One or more example embodiments provide a semiconductor package, and more particularly, to a semiconductor package including an optical printed circuit board (PCB) with an optical waveguide capable of reducing optical loss.

According to an aspect of an example embodiment, a semiconductor package includes: an optical printed circuit board (PCB); and an integrated circuit device on the optical PCB, wherein the optical PCB includes: a base layer; at least one photoimageable dielectric (PID) layer on the base layer; a horizontal optical waveguide extending in a horizontal direction in the at least one PID layer; a first via optical waveguide on a first side of the horizontal optical waveguide, in optical communication with the horizontal optical waveguide, and extending perpendicular to the at least one PID layer; and a second via optical waveguide on a second side of the horizontal optical waveguide, in optical communication with the horizontal optical waveguide, and extending in a vertical direction.

According to an aspect of an example embodiment, a semiconductor package includes: an optical printed circuit board (PCB); and an integrated circuit device on the optical PCB, wherein the optical PCB includes: a base layer; a lower photoimageable dielectric (PID) layer on the base layer; an upper PID layer on the lower PID layer; a horizontal optical waveguide extending in a horizontal direction in the lower PID layer; a first via optical waveguide on a first side of the horizontal optical waveguide, in optical communication with the horizontal optical waveguide, and extending in a direction perpendicular to the lower PID layer and perpendicular to the upper PID layer; and a second via optical waveguide on a second side of the horizontal optical waveguide, in optical communication with the horizontal optical waveguide, and extending perpendicular to the lower PID layer and perpendicular to the upper PID layer.

According to an aspect of an example embodiment, a semiconductor package includes: an optical printed circuit board (PCB); and an integrated circuit device on the optical PCB, wherein the optical PCB includes: a base layer; a base optical waveguide extending in a horizontal direction and a vertical direction in the base layer; a photoimageable dielectric (PID) layer on the base layer; a first via optical waveguide on a first side of the base optical waveguide, in optical communication with the base optical waveguide, and extending perpendicular to the PID layer; and a second via optical waveguide on a second side of the base optical waveguide, in optical communication with the base optical waveguide, and extending perpendicular to the PID layer.

### BRIEF DESCRIPTION OF THE DRAWINGS

Embodiments will be more clearly understood from the following detailed description taken in conjunction with the accompanying drawings, in which:

FIG. 1 is a plan view illustrating a semiconductor package according to one or more example embodiments;

FIGS. 2A and 2B are cross-sectional views illustrating an optical printed circuit board (PCB) according to one or more example embodiments;

FIGS. 3A and 3B are cross-sectional views illustrating an optical printed circuit board (PCB) according to one or more example embodiments;

FIG. 4 is a perspective view illustrating the optical PCB illustrated in FIG. 3A according to one or more example embodiments;

FIGS. 5A, 5B, 5C, 5D and 5E are cross-sectional views illustrating a method of manufacturing the optical PCB illustrated in FIGS. 2A and 2B according to one or more example embodiments;

FIGS. 6A, 6B and 6C are cross-sectional views illustrating a method of manufacturing the optical PCB illustrated in FIGS. 3A, 3B, and 4 according to one or more example embodiments;

FIGS. 7A, 7B, 7C and 7D are cross-sectional views illustrating optical waveguides included in optical PCBs of one or more example embodiments;

FIG. 8 is a cross-sectional view illustrating an optical PCB according to one or more example embodiments;

FIGS. 9A and 9B are cross-sectional views illustrating an optical PCB according to one or more example embodiments;

FIGS. 10A and 10B are cross-sectional views illustrating an optical PCB according to one or more example embodiments;

FIGS. 11A and 11B are cross-sectional views illustrating an optical PCB according to one or more example embodiments;

FIGS. 12A, 12B, 12C and 12D are cross-sectional views illustrating a method of manufacturing the optical PCB illustrated in FIGS. 9A and 9B according to one or more example embodiments; and

FIG. 13 is a diagram for explaining optical characteristics of a PID layer used for an optical PCB according to one or more example embodiments and a comparative dielectric layer of a comparative example.

### DETAILED DESCRIPTION

Hereinafter, example embodiments will be described in detail with reference to the accompanying drawings. The following embodiments may be implemented in only one, or may be implemented in combination of one or more embodiments. Therefore, the inventive concept should not be construed as being limited to one embodiment.

Herein, singular forms of components may include plural forms unless the context clearly indicates otherwise. Further, drawings may be exaggerated to describe one or more example embodiments more clearly. As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

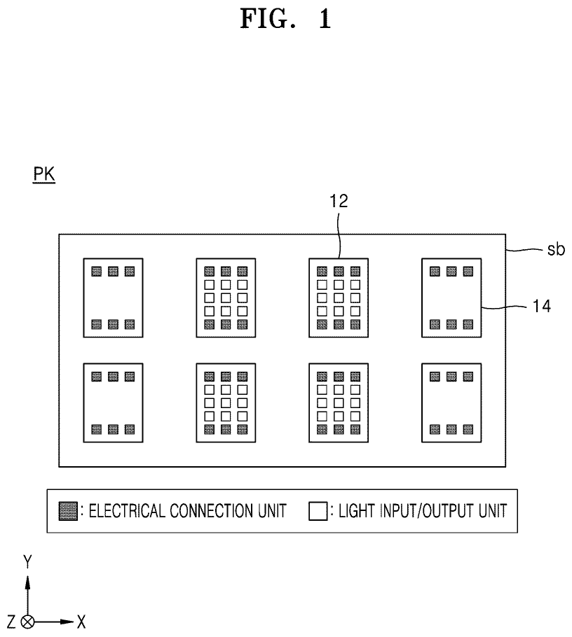

FIG. 1 is a plan view illustrating a semiconductor package PK according to one or more example embodiments.

Specifically, the semiconductor package PK of one or more example embodiments may include a plurality of integrated circuit devices mounted on an optical printed circuit board (PCB) sb. The semiconductor package PK may be referred to as an optical integrated circuit package. The optical PCB sb may be referred to as an optical substrate or an optical integrated circuit board.

The plurality of integrated circuit devices may further include an optical element 12 and an electrical element 14. The optical element 12 may include a photoelectric element (or a photoelectric conversion element). The photoelectric element may include a photodetector PD. The optical element 12 may include an electro-optical element (or an electro-optical conversion element). The electro-optical element may include a laser diode LD. The optical element 12 may include both the photoelectric element and the electro-optical element.

The optical element 12 may include an optical input/output unit and an electrical connection unit. The optical input/output unit may be optically connected to an optical waveguide formed on the optical PCB sb. The optical waveguide may be a path through which light (or an optical signal) travels. The electrical connection unit may be electrically connected to a connection terminal formed on the optical PCB sb.

The electrical element 14 may be spaced apart from the optical element 12 on the optical PCB sb. The electrical element 14 may be for driving the optical element 12. The electrical element 14 may be electrically connected to the optical element 12 through a wiring line formed on the optical PCB sb. The electrical element 14 may include the electrical connection unit.

For convenience, although it is illustrated in FIG. 1 that both the optical element 12 and the electrical element 14 are integrated on the optical PCB sb, the electrical element 14 may not be integrated on the optical PCB sb and may be formed on a separate circuit board in a module or a system.

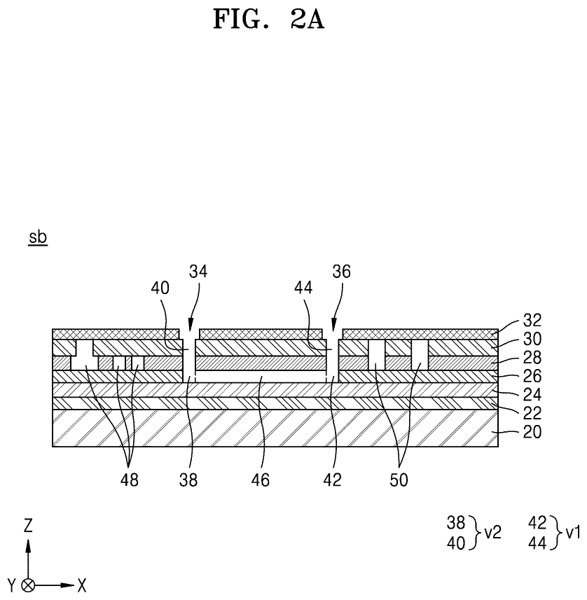

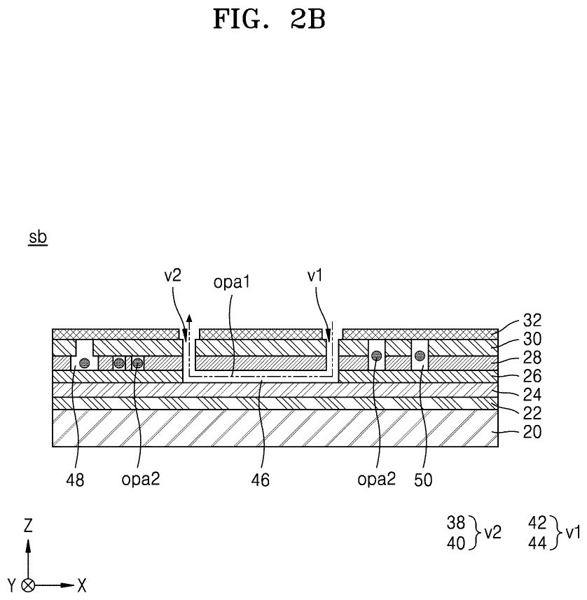

FIGS. 2A and 2B are cross-sectional views illustrating an optical PCB sb according to one or more example embodiments.

Specifically, the optical PCB sb may be used for the semiconductor package PK of FIG. 1. The optical PCB sb may include a base layer 20, a lower anti-reflection layer 22, a lower metal layer 24, and a lower photoimageable dielectric (PID) layer 26.

The optical PCB sb may include an upper metal layer 28, an upper PID layer 30, and an upper anti-reflection layer 32. The optical PCB sb may include a horizontal optical waveguide 46, first and second via optical waveguides v1 and v2, and first and second additional via optical waveguides 50 and 48.

The base layer 20 may be referred to as a base substrate. In one or more example embodiments, the base layer 20 may include flame retardant 4 (FR4) including epoxy resin and glass fiber. The lower anti-reflection layer 22 may be arranged on the base layer 20. The lower anti-reflection layer 22 may include a material layer for preventing reflection of ultraviolet rays. The lower anti-reflection layer 22 may be referred to as a lower anti-reflection coating layer. The lower anti-reflection layer 22 may serve to prevent reflection of the optical signal transmitted to the horizontal optical waveguide 46.

Reflectance of the lower anti-reflection layer 22 with respect to ultraviolet rays may be 0.5 % or less. Reflectance of the lower anti-reflection layer 22 with respect to ultraviolet rays may be about 0.2 % to about 0.3 %. In one or more example embodiments, the lower anti-reflection layer 22 may include titanium oxide (TiO₂), magnesium fluoride (MgF₂), or a combination thereof.

The lower metal layer 24 may be arranged on the lower anti-reflection layer 22. The lower metal layer 24 may be referred to as a lower metal seed layer. The lower metal layer 24 may be in contact with the horizontal optical waveguide 46. The lower metal layer 24 may include a metal seed of about 50 nm to about 300 nm. Because the lower metal layer 24 has a small surface roughness of about 50 nm to about 300 nm, reflection or scattering of the optical signal traveling through the horizontal optical waveguide 46 may be reduced. The lower metal layer 24 may include a copper (Cu) layer.

The lower PID layer 26 may be arranged on the lower metal layer 24. The lower PID layer 26 may include an organic layer. In one or more example embodiments, the lower PID layer 26 may include a material layer including novolac resin. In one or more example embodiments, the lower PID layer 26 may include a material layer including polyimide (PI) resin or polybenzoxazole (PBO) resin.

The horizontal optical waveguide 46 extending in a first horizontal direction (X direction) may be arranged in the lower PID layer 26. The lower PID layer 26 may include first and second lower via optical waveguides 42 and 38 arranged in a vertical direction (Z direction) and in connection with the horizontal optical waveguide 46.

The horizontal optical waveguide 46 and the first and second lower via optical waveguides 42 and 38 may be arranged in the lower PID layer 26. The horizontal optical waveguide 46 may include a horizontal cavity arranged in the lower PID layer 26.

The horizontal optical waveguide 46, and the first and second lower via optical waveguides 42 and 38 may be formed in the lower PID layer 26 by a photo process. Accordingly, the horizontal optical waveguide 46 and the first and second lower via optical waveguides 42 and 38 may be easily adjusted in size and may be formed into various structures.

The horizontal optical waveguide 46 and the first and second lower via optical waveguides 42 and 38 may be provided in the lower PID layer 26 to reduce light reflectance and light diffuse reflectance and to reduce optical loss.

In one or more example embodiments, the diffuse reflectance of the horizontal optical waveguide 46 and the first and second lower via optical waveguides 42 and 38 with respect to ultraviolet rays may be less than or equal to 3%, for example, about 1% to about 3%. In addition, the optical PCB sb may include the lower PID layer 26 to reduce a coefficient of thermal expansion (CTE) and to reduce the possibility of mechanical deformation due to temperature changes.

The upper metal layer 28 may be arranged on the lower PID layer 26 excluding the horizontal optical waveguide 46 and the first and second lower via optical waveguides 42 and 38. The first and second lower via optical waveguides 42 and 38 may extend in the vertical direction (Z direction) in the upper metal layer 28.

The upper metal layer 28 may be referred to as an upper metal seed layer. The upper metal layer 28 may be in contact with the first and second lower via optical waveguides 42 and 38. The upper metal layer 28 may include a metal seed of about 50 nm to about 300 nm. Because the upper metal layer 28 has a small surface roughness of about 50 nm to about 300 nm, reflection or scattering of an optical signal traveling through the first and second lower via optical waveguides 42 and 38 may be reduced. The upper metal layer 28 may include a Cu layer. The first and second additional via optical waveguides 50 and 48 may be formed in the upper metal layer 28 or the upper PID layer 30.

The upper PID layer 30 may be arranged on the upper metal layer 28 excluding the horizontal optical waveguide 46 and the first and second lower via optical waveguides 42 and 38. The upper PID layer 30 may include an organic layer. In one or more example embodiments, the upper PID layer 30 may include a material layer including novolac resin. In one or more example embodiments, the upper PID layer 30 may include a material layer including polyimide (PI) resin or polybenzoxazole (PBO) resin.

First and second upper via optical waveguides 44 and 40 may be arranged in the upper PID layer 30. The first and second upper via optical waveguides 44 and 40 may be formed in the upper PID layer 30 by a photo process. Accordingly, the first and second upper via optical waveguides 44 and 40 may be easily adjusted in size and formed into various structures.

The first and second upper via optical waveguides 44 and 40 may be provided in the upper PID layer 30 to reduce light reflectance and light diffuse reflectance and to reduce optical loss. In addition, the optical PCB sb includes the upper PID layer 30 to reduce a coefficient of thermal expansion (CTE) and to reduce the possibility of mechanical deformation due to temperature changes.

The upper anti-reflection layer 32 may be arranged on the upper PID layer 30 excluding the horizontal optical waveguide 46, the first and second lower via optical waveguides 42 and 38, and the first and second upper via optical waveguides 44 and 40. The upper anti-reflection layer 32 may expose the first and second upper via optical waveguides 44 and 40.

The upper anti-reflection layer 32 may include a material layer for preventing reflection of ultraviolet rays. The upper anti-reflection layer 32 may be referred to as an upper anti-reflection coating layer. The upper anti-reflection layer 32 may serve to prevent reflection of an optical signal transmitted to the first and second upper via optical waveguides 44 and 40.

Reflectance of the upper anti-reflection layer 32 with respect to ultraviolet rays may be 0.5% or less. Reflectance of the upper anti-reflection layer 32 with respect to ultraviolet rays may be about 0.2% to about 0.3%. In one or more example embodiments, the upper anti-reflection layer 32 may include titanium oxide (TiO₂), magnesium fluoride (MgF₂), or a combination thereof.

The first lower via optical waveguide 42 and the first upper via optical waveguide 44 may constitute the first via optical waveguide v1. The first via optical waveguide v1 may include a vertical cavity penetrating tops and bottoms of the lower PID layer 26 and the upper PID layer 30 in the vertical direction (Z direction).

The first via optical waveguide v1 may constitute a first light input/output unit 36. The second lower via optical waveguide 38 and the second upper via optical waveguide 40 may constitute the second via optical waveguide v2. The second via optical waveguide v2 may include a vertical cavity penetrating tops and bottoms of the lower PID layer 26 and the upper PID layer 30 in the vertical direction (Z direction). The second via optical waveguide v2 may constitute a second light input/output unit 34.

Here, an optical path of the optical PCB sb is described with reference to FIG. 2B. The optical PCB sb may include a first optical path opa1 passing through the first via optical waveguide v1, the horizontal optical waveguide 46, and the second via optical waveguide v2. Light may be transmitted between the first light input/output unit 36 of FIG. 2A and the second light input/output unit 34 of FIG. 2A in the first optical path opa1. Light may be transmitted in the first optical path opa1 in the first horizontal direction (X direction) and the vertical direction (Z direction).

The optical PCB sb may include a second optical path opa2 arranged in the first and second additional via optical waveguides 50 and 48. The second optical path opa2 may extend in a second horizontal direction (Y direction). Light may be transmitted in the second optical path opa2 in the second horizontal direction (Y direction).

The optical PCB sb, as described above, may transmit light while reducing optical loss in the first horizontal direction (X direction), the second horizontal direction (Y direction), and the vertical direction (Z direction) through the horizontal optical waveguide 46, the first and second via optical waveguides v1 and v2, and the first and second additional via optical waveguides 50 and 48.

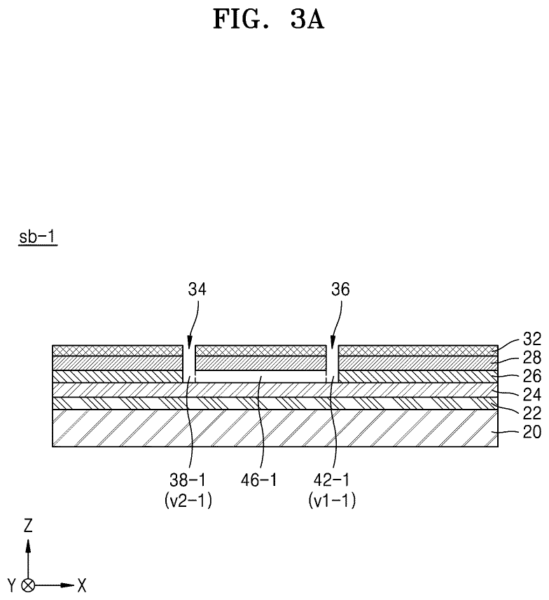

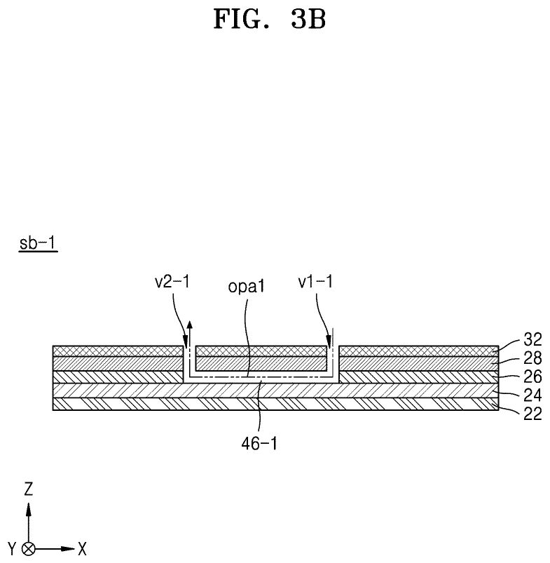

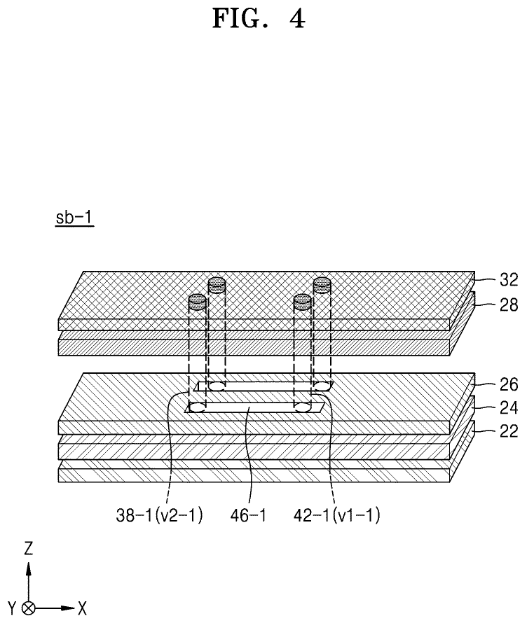

FIGS. 3A and 3B are cross-sectional views illustrating an optical PCB sb-1 according to one or more example embodiments and FIG. 4 is a perspective view illustrating the optical PCB illustrated in FIG. 3A according to one or more example embodiments.

Specifically, the optical PCB sb-1 may be used for the semiconductor package PK of FIG. 1. The optical PCB sb-1 may be almost the same as the optical PCB sb of FIGS. 2A and 2B except that an upper PID layer and additional via optical waveguides are not formed.

In FIGS. 3A, 3B, and 4, the same reference numerals as in FIG. 2A and FIG. 2B denote the same members. In FIGS. 3A, 3B, and 4, duplicative description previously given with reference to FIGS. 2A and 2B will be briefly given or omitted.

The optical PCB sb-1 may include a base layer 20, a lower anti-reflection layer 22, a lower metal layer 24, a lower PID layer 26, an upper metal layer 28, and an upper anti-reflection layer 32. The optical PCB sb-1 may include a horizontal optical waveguide 46-1 and first and second via optical waveguides v1-1 and v2-1.

The base layer 20 may be referred to as a base substrate. The lower anti-reflection layer 22 may be arranged on the base layer 20. The lower anti-reflection layer 22 may be referred to as a lower anti-reflection coating layer. The lower anti-reflection layer 22 may serve to prevent reflection of an optical signal transmitted to the horizontal optical waveguide 46-1.

The lower metal layer 24 may be arranged on the lower anti-reflection layer 22. The lower metal layer 24 may be referred to as a lower metal seed layer. The lower metal layer 24 may be in contact with the horizontal optical waveguide 46-1. Because the lower metal layer 24 has a small surface roughness of about 50 nm to about 300 nm, reflection or scattering of the optical signal traveling through the horizontal optical waveguide 46-1 may be reduced.

The lower PID layer 26 may be arranged on the lower metal layer 24. The lower PID layer 26 may include an organic layer. The horizontal optical waveguide 46-1 extending in the first horizontal direction (X direction) may be arranged in the lower PID layer 26. The lower PID layer 26 may include first and second lower via optical waveguides 42-1 and 38-1 arranged in the vertical direction (Z direction) and in connection with the horizontal optical waveguide 46-1.

The horizontal optical waveguide 46 and the first and second lower via optical waveguides 42-1 and 38-1 may be arranged in the lower PID layer 26. The first and second lower via optical waveguides 42-1 and 38-1 may extend in the vertical direction (Z direction). A plurality of first lower via optical waveguides 42-1 and a plurality of second lower via optical waveguides 38-1 may be arranged in the second horizontal direction (Y direction) as illustrated in FIG. 4.

The horizontal optical waveguide 46-1 and the first and second lower via optical waveguides 42-1 and 38-1 may be formed in the lower PID layer 26 by a photo process. Accordingly, the horizontal optical waveguide 46-1 and the first and second lower via optical waveguides 42-1 and 38-1 may be easily adjusted in size and formed into various structures.

The horizontal optical waveguide 46-1 and the first and second lower via optical waveguides 42-1 and 38-1 may be provided in the lower PID layer 26 to reduce light reflectance and light diffuse reflectance and to reduce optical loss.

In one or more example embodiments, the diffuse reflectance of the first and second lower via optical waveguides 42-1 and 38-1 with respect to ultraviolet rays may be less than or equal to 3%, for example, about 1% to about 3%. In addition, the optical PCB sb-1 may include the lower PID layer 26 to reduce a coefficient of thermal expansion (CTE) and to reduce the possibility of mechanical deformation due to temperature changes.

The upper metal layer 28 may be arranged on the lower PID layer 26 excluding the horizontal optical waveguide 46 and the first and second lower via optical waveguides 42-1 and 38-1. The first and second lower via optical waveguides 42-1 and 38-1 may extend in the vertical direction (Z direction) in the upper metal layer 28.

The upper metal layer 28 may be referred to as an upper metal seed layer. The upper metal layer 28 may be in contact with the first and second lower via optical waveguides 42-1 and 38-1. Because the upper metal layer 28 has a small surface roughness of about 50 nm to about 300 nm, reflection or scattering of an optical signal traveling through the first and second lower via optical waveguides 42-1 and 38-1 may be reduced.

The upper anti-reflection layer 32 may be arranged on the upper PID layer 30 excluding the horizontal optical waveguide 46-1 and the first and second lower via optical waveguides 42-1 and 38-1. The upper anti-reflection layer 32 may expose the first and second lower via optical waveguides 42-1 and 38-1.

The upper anti-reflection layer 32 may include a material layer for preventing reflection of ultraviolet rays. The upper anti-reflection layer 32 may be referred to as an upper anti-reflection coating layer. The upper anti-reflection layer 32 may serve to prevent reflection of an optical signal transmitted to the first and second lower via optical waveguides 42-1 and 38-1.

The first lower via optical waveguide 42-1 may constitute the first via optical waveguide v1-1. The first via optical waveguide v1-1 may constitute a first light input/output unit 36. The second lower via optical waveguide 38-1 may constitute a second via optical waveguide v2-1. The second via optical waveguide v2-1 may constitute a second light input/output unit 34.

Below, an optical path of the optical PCB sb-1 is described with reference to FIG. 3B. The optical PCB sb-1 may include a first optical path opa1 passing through the first via optical waveguide v1-1, the horizontal optical waveguide 46-1, and the second via optical waveguide v2-1. Light may be transmitted between the first light input/output unit 36 of FIG. 3A and the second light input/output unit 34 of FIG. 3A in the first optical path opa1. Light may be transmitted in the first optical path opa1 in the first horizontal direction (X direction) and the vertical direction (Z direction).

The optical PCB sb-1 as described above may transmit light while reducing optical loss in the first horizontal direction (X direction) and the vertical direction (Z direction) through the horizontal optical waveguide 46-1 and the first and second via optical waveguides v1-1 and v2-1.

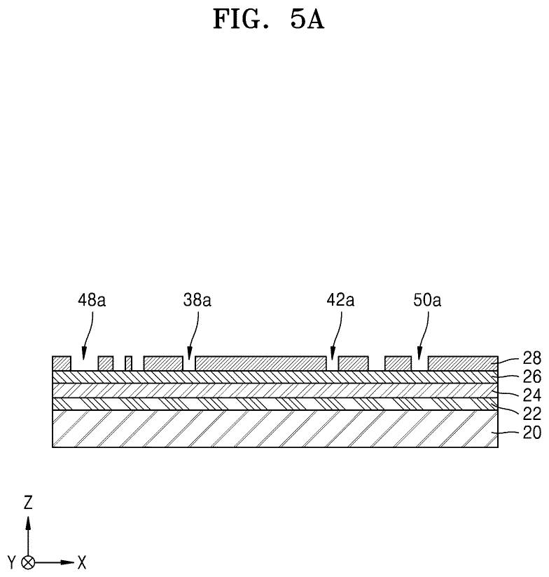

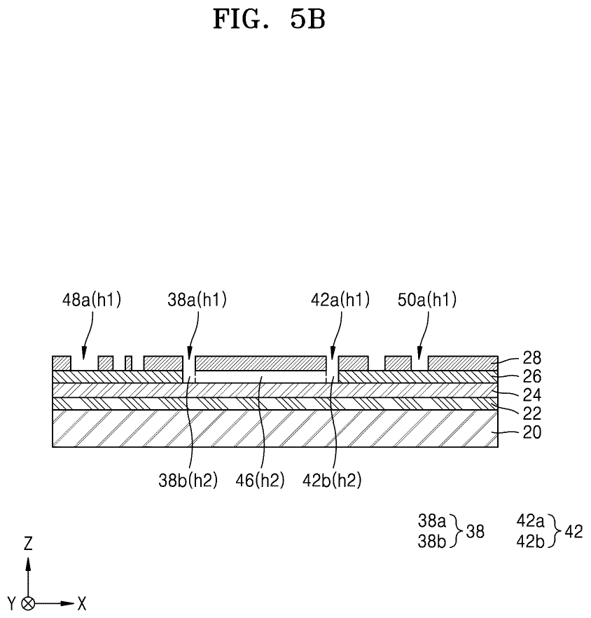

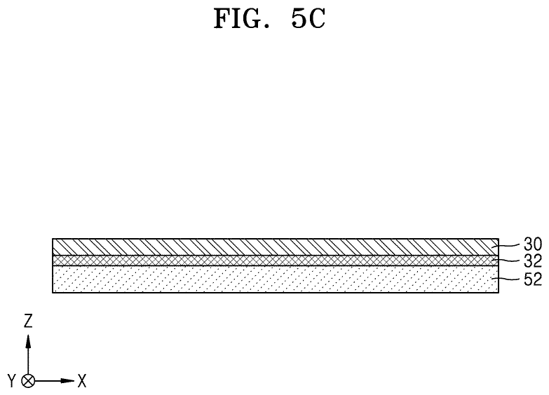

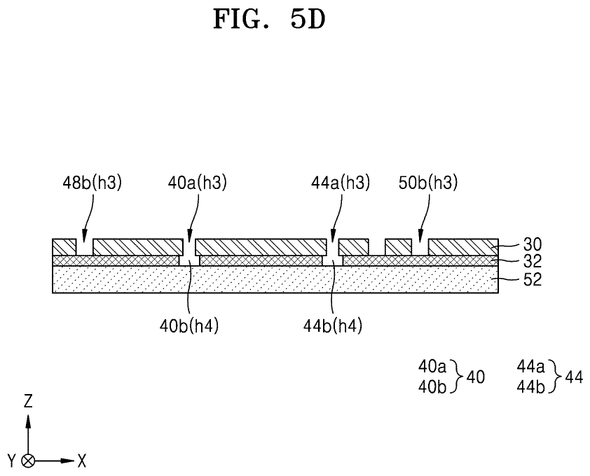

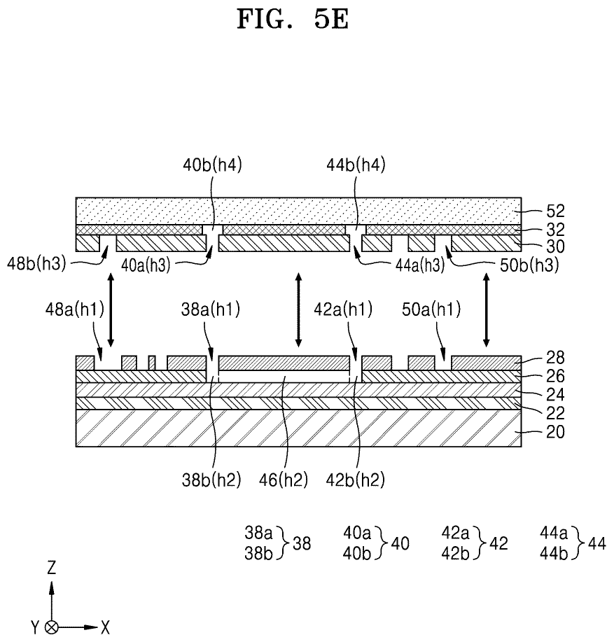

FIGS. 5A, 5B, 5C, 5D and 5E are cross-sectional views illustrating a method of manufacturing the optical PCB illustrated in FIGS. 2A and 2B according to one or more example embodiments.

Specifically, in FIGS. 5A, 5B, 5C, 5D and 5E, the same reference numerals as in FIG. 2A and FIG. 2B denote the same members. In FIGS. 5A, 5B, 5C, 5D and 5E, duplicative description previously given with reference to FIGS. 2A and 2B will be briefly given or omitted.

Referring to FIG. 5A, a base layer 20 may be prepared. The base layer 20 may be referred to as a base substrate. In one or more example embodiments, the base layer 20 may include flame retardant 4 (FR4) including epoxy resin and glass fiber.

Next, a lower anti-reflection layer 22 may be formed on the base layer 20. The lower anti-reflection layer 22 may include a material layer for preventing reflection of ultraviolet rays. The lower anti-reflection layer 22 may be referred to as a lower anti-reflection coating layer. In one or more example embodiments, the lower anti-reflection layer 22 may include titanium oxide (TiO₂), magnesium fluoride (MgF₂), or a combination thereof.

The lower metal layer 24 may be formed on the lower anti-reflection layer 22. The lower metal layer 24 may be referred to as a lower metal seed layer. The lower metal layer 24 may include a metal seed of about 50 nm to about 300 nm. The lower metal layer 24 has a small surface roughness of about 50 nm to about 300 nm. The lower metal layer 24 may include a copper (Cu) layer.

The lower PID layer 26 may be formed on the lower metal layer 24. The lower PID layer 26 may include an organic layer. In one or more example embodiments, the lower PID layer 26 may include a material layer including novolac resin. In one or more example embodiments, the lower PID layer 26 may include a material layer including polyimide (PI) resin or polybenzoxazole (PBO) resin.

The upper metal layer 28 may be formed on the lower PID layer 26. Next, a plurality of first holes h1 may be formed in the upper metal layer 28. The plurality of first holes h1 may be formed by a photolithography process. The plurality of first holes h1 may be formed by patterning the upper metal layer 28 by a photo process and an etching process.

The plurality of first holes h1 may include a plurality of first cavities. The plurality of first holes h1 may be spaced apart from one another. The plurality of first holes h1 may include first and second preliminary lower via optical waveguides 42a and 38a and first and second preliminary additional via optical waveguides 50a and 48a.

Referring to FIG. 5B, a second hole h2 may be formed on the lower PID layer 26. The second hole h2 may be formed by a photolithography process. The second hole h2 may be formed by patterning the lower PID layer 26 by a photo process and an etching process.

The second hole h2 may include a second cavity. The second hole h2 may extend in the first horizontal direction (X direction). The second hole h2 may include a third preliminary lower via optical waveguide 42b, a fourth preliminary lower via optical waveguide 38b, and a horizontal optical waveguide 46.

The third preliminary lower via optical waveguide 42b may be arranged on one side of the second hole h2. The fourth preliminary lower via optical waveguide 38b may be arranged on the other side of the second hole h2. The third preliminary lower via optical waveguide 42b and the fourth preliminary lower via optical waveguide 38b may be connected to each other by the horizontal optical waveguide 46.

The third preliminary lower via optical waveguide 42b may be aligned with the first preliminary lower via optical waveguide 42a. The fourth preliminary lower via optical waveguide 38b may be aligned with the second preliminary lower via optical waveguide 38a.

Accordingly, the first and third preliminary lower via optical waveguides 42a and 42b may constitute the first lower via optical waveguide 42. The second preliminary lower via optical waveguide 38a and the fourth preliminary lower via optical waveguide 38b may constitute the second lower via optical waveguide 38.

For convenience, it is illustrated in FIGS. 5A and 5B that the plurality of first holes h1 are formed in the upper metal layer 28, and then the second hole h2 may be formed on the lower PID layer 26. In one or more example embodiments, after forming the second hole h2 on the lower PID layer 26, the plurality of first holes h1 may be formed in the upper metal layer 28 to be aligned with the second hole h2.

Referring to FIG. 5C, a second base layer 52 may be prepared. The second base layer 52 may be referred to as a second base substrate. In one or more example embodiments, the second base layer 52 may include flame retardant 4 (FR4) including epoxy resin and glass fiber.

Next, the upper anti-reflection layer 32 may be formed on the second base layer 52. The upper anti-reflection layer 32 may include a material layer for preventing reflection of ultraviolet rays. The upper anti-reflection layer 32 may be referred to as an upper anti-reflection coating layer.

The upper PID layer 30 may be formed on the upper anti-reflection layer 32. The upper PID layer 30 may include an organic layer. In one or more example embodiments, the upper PID layer 30 may include a material layer including novolac resin. In one or more example embodiments, the upper PID layer 30 may include a material layer including polyimide (PI) resin or polybenzoxazole (PBO) resin.

Referring to FIG. 5D, a plurality of third holes h3 may be formed on the upper PID layer 30. The plurality of third holes h3 may be formed by a photolithography process. The plurality of third holes h3 may be formed by patterning the upper PID layer 30 by a photo process and an etching process.

The plurality of third holes h3 may include a plurality of third cavities. The plurality of third holes h3 may be spaced apart from one another in the first horizontal direction (X direction). The plurality of third holes h3 may include first and second preliminary upper via optical waveguides 44a and 40a and third and fourth preliminary additional via optical waveguides 50b and 48b.

Subsequently, a plurality of fourth holes h4 may be formed by patterning the upper anti-reflection layer 32. The plurality of fourth holes h4 may include a third preliminary upper via optical waveguide 44b and a fourth preliminary upper via optical waveguide 40b. The third preliminary upper via optical waveguide 44b may be aligned with the first preliminary upper via optical waveguide 44a. The fourth preliminary upper via optical waveguide 40b may be aligned with the second preliminary upper via optical waveguide 40a.

Accordingly, the first and third preliminary upper via optical waveguides 44a and 44b may constitute the first upper via optical waveguide 44. The second preliminary upper via optical waveguide 40a and the fourth preliminary upper via optical waveguide 40b may constitute the second upper via optical waveguide 40.

For convenience, it is illustrated in FIG. 5D that the plurality of third holes h3 are formed in the upper PID layer 30, and then the plurality of fourth holes h4 are formed in the upper anti-reflection layer 32. In one or more example embodiments, after forming the plurality of fourth holes h4 in the upper anti-reflection layer 32, the plurality of third holes h3 may be formed on the upper PID layer 30.

Referring to FIG. 5E, the result of FIG. 5D may be overturned and positioned on the result of FIG. 5B. Next, the overturned result of FIG. 5D may be aligned on the result of FIG. 5B to be bonded. The first lower via optical waveguide 42 and the first upper via optical waveguide 44 may be aligned with each other to be bonded. The second lower via optical waveguide 38 and the second upper via optical waveguide 40 may be aligned with each other to be bonded.

The first and third preliminary additional via optical waveguides 50a and 50b may be aligned with each other to be bonded. The second preliminary additional via optical waveguide 48a and the fourth preliminary additional via optical waveguide 48b may be aligned with each other to be bonded. The optical PCB sb illustrated in FIGS. 2A and 2B may be manufactured by the above processes.

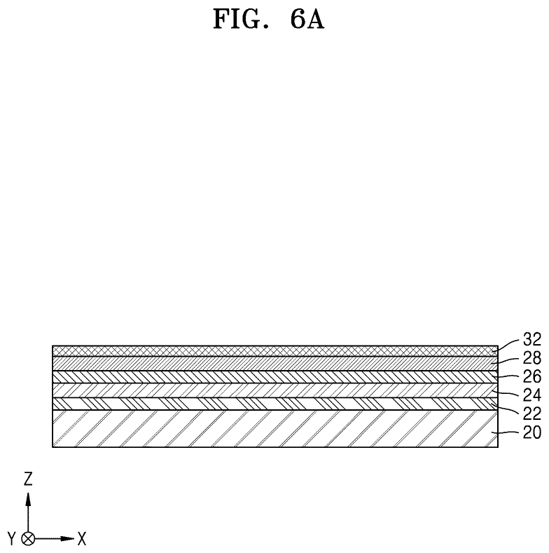

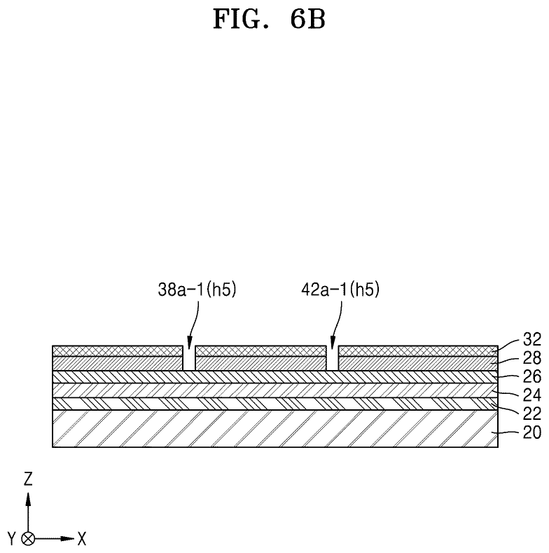

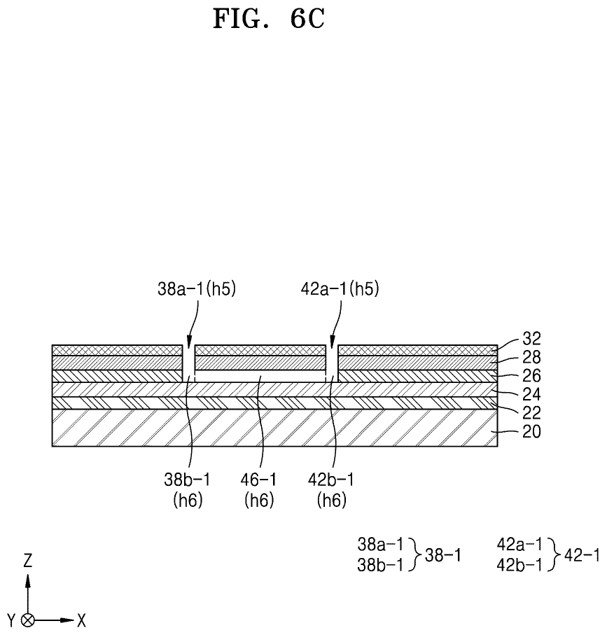

FIGS. 6A, 6B and 6C are cross-sectional views illustrating a method of manufacturing the optical PCB illustrated in FIGS. 3A, 3B, and 4 according to one or more example embodiments.

Specifically, in FIGS. 6A, 6B and 6C, the same reference numerals as in FIGS. 3A, 3B, and 4 denote the same members. In FIGS. 6A, 6B and 6C, duplicative description previously given with reference to FIGS. 3A, 3B, and 4 will be briefly given or omitted.

Referring to FIG. 6A, a base layer 20 may be prepared. The base layer 20 may be referred to as a base substrate. In one or more example embodiments, the base layer 20 may include flame retardant 4 (FR4) including epoxy resin and glass fiber.

Next, a lower anti-reflection layer 22 may be formed on the base layer 20. The lower anti-reflection layer 22 may include a material layer for preventing reflection of ultraviolet rays. The lower anti-reflection layer 22 may be referred to as a lower anti-reflection coating layer. In one or more example embodiments, the lower anti-reflection layer 22 may include titanium oxide (TiO₂), magnesium fluoride (MgF₂), or a combination thereof.

The lower metal layer 24 may be formed on the lower anti-reflection layer 22. The lower metal layer 24 may be referred to as a lower metal seed layer. The lower metal layer 24 may include a metal seed of about 50 nm to about 300 nm. The lower metal layer 24 may have a small surface roughness of about 50 nm to about 300 nm. The lower metal layer 24 may include a copper (Cu) layer.

The lower PID layer 26 may be formed on the lower metal layer 24. The lower PID layer 26 may include an organic layer. In one or more example embodiments, the lower PID layer 26 may include a material layer including novolac resin. In one or more example embodiments, the lower PID layer 26 may include a material layer including polyimide (PI) resin or polybenzoxazole (PBO) resin.

The upper metal layer 28 may be formed on the lower PID layer 26. The upper metal layer 28 may be referred to as an upper metal seed layer. The upper metal layer 28 may include a Cu layer.

The upper anti-reflection layer 32 may be formed on the upper metal layer 28. The upper anti-reflection layer 32 may include a material layer for preventing reflection of ultraviolet rays. The upper anti-reflection layer 32 may be referred to as an upper anti-reflection coating layer.

Referring to FIG. 6B, a plurality of fifth holes h5 may be formed in the upper anti-reflection layer 32 and the upper metal layer 28. The plurality of fifth holes h5 may be formed by a photolithography process. The plurality of fifth holes h5 may be formed by patterning the upper anti-reflection layer 32 and the upper metal layer 28 by a photo process and an etching process.

The plurality of fifth holes h5 may include a plurality of fifth cavities. The plurality of fifth holes h5 may be spaced apart from one another in the first horizontal direction (X direction). The plurality of fifth holes h5 may extend in the vertical direction (Z direction). The plurality of fifth holes h5 may include first and second preliminary lower via optical waveguides 42a-1 and 38a-1.

Referring to FIG. 6C, a sixth hole h6 may be formed on the lower PID layer 26. The sixth hole h6 may be formed by a photolithography process. The sixth hole h6 may be formed by patterning the lower PID layer 26 by a photo process and an etching process.

The sixth hole h6 may include a sixth cavity. The sixth hole h6 may extend in the first horizontal direction (X direction). The sixth hole h6 may include a third preliminary lower via optical waveguide 42b-1, a fourth preliminary lower via optical waveguide 38b-1, and a horizontal optical waveguide 46-1.

The third preliminary lower via optical waveguide 42b-1 may be arranged on one side of the sixth hole h6. The fourth preliminary lower via optical waveguide 38b-1 may be arranged on the other side of the sixth hole h6. The third preliminary lower via optical waveguide 42b-1 and the fourth preliminary lower via optical waveguide 38b-1 may be connected to each other by the horizontal optical waveguide 46-1.

The third preliminary lower via optical waveguide 42b-1 may be aligned with the third preliminary lower via optical waveguide 42a-1. The fourth preliminary lower via optical waveguide 38b-1 may be aligned with the second preliminary lower via optical waveguide 38a-1.

Accordingly, the first and third preliminary lower via optical waveguides 42a-1 and 42b-1 may constitute the first lower via optical waveguide 42-1. The second preliminary lower via optical waveguide 38a-1 and the fourth preliminary lower via optical waveguide 38b-1 may constitute the second lower via optical waveguide 38-1.

For convenience, it is illustrated in FIGS. 6B and 6C that the plurality of fifth holes h5 are formed in the upper anti-reflection layer 32 and the upper metal layer 28, and then the sixth hole h6 may be formed in the lower PID layer 26. In one or more example embodiments, after forming the sixth hole h6 in the lower PID layer 26, the plurality of fifth holes h5 may be formed in the upper anti-reflection layer 32 and the upper metal layer 28 to be aligned with the sixth hole h6.

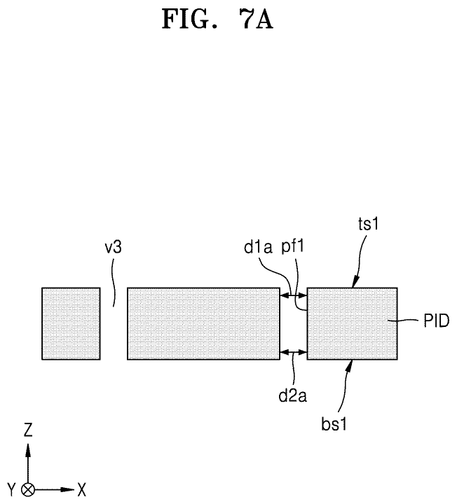

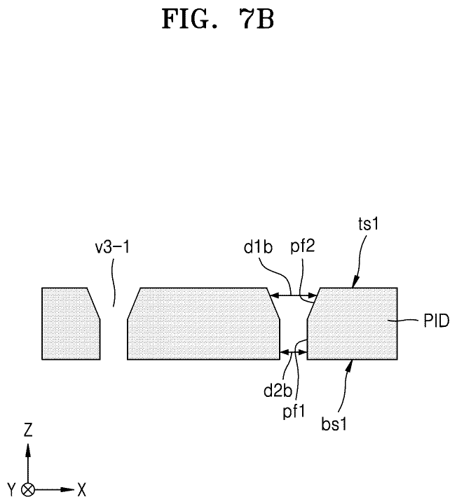

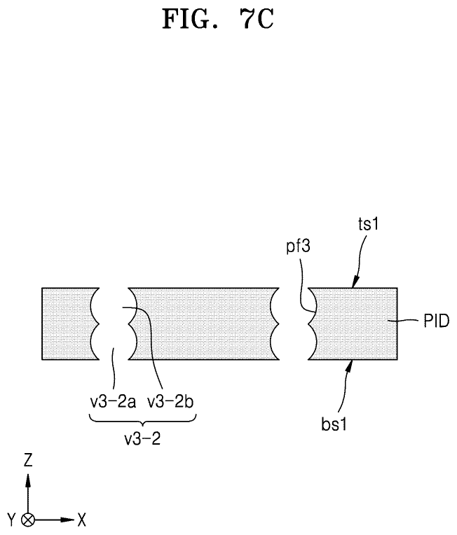

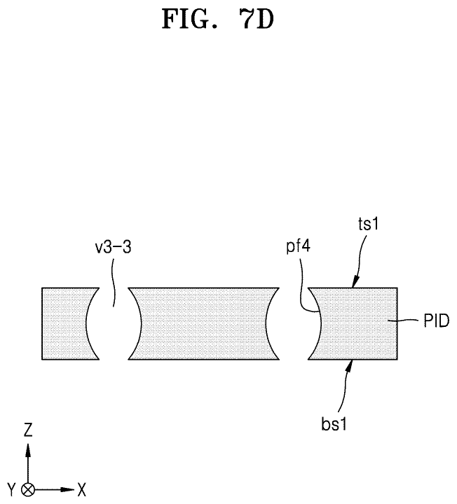

FIGS. 7A, 7B, 7C and 7D are cross-sectional views illustrating optical waveguides included in optical PCBs of one or more example embodiments.

Specifically, as described above, the optical PCB sb of FIGS. 2A and 2B may include the first and second via optical waveguides v1 and v2 and the first and second additional via optical waveguides 50 and 48.

Light may be transmitted through the first and second via optical waveguides v1 and v2 of FIGS. 2A and 2B and the first and second additional via optical waveguides 50 and 48 in the lower PID layer 26 and the upper PID layer 30.

As described above, the optical PCB sb-1 of FIGS. 3A, 3B, and 4 may include the first and second via optical waveguides v1-1 and v2-1. Light may be transmitted through the first and second via optical waveguides v1-1 and v2-1 of FIGS. 3A, 3B, and 4B in the lower PID layer 26.

Considering FIGS. 2A, 2B, 3A, 3B, and 4, the optical PCBs sb and sb-1 may have the via optical waveguides formed in the PID layer PID. Various examples of the via optical waveguides are described with reference to FIGS. 7A, 7B, 7C and 7D.

As illustrated in FIG. 7A, a via optical waveguide v3 may include a vertical cavity penetrating a top ts1 and a bottom bs1 of the PID layer PID. One side surface pf1 of the via optical waveguide v3 may have a straight line shape in the vertical direction. In a vertical cross-section of the via optical waveguide v3, an upper distance d1a may be equal to a lower distance d2a.

As illustrated in FIG. 7B, a via optical waveguide v3-1 may include a vertical cavity penetrating a top ts1 and a bottom bs1 of the PID layer PID. One side surface pf2 of the via optical waveguide v3-1 may have a shape inclined in a horizontal direction. In a vertical cross-section of the via optical waveguide v3-1, an upper distance d1b may be greater than a lower distance d2b.

As illustrated in FIG. 7C, a via optical waveguide v3-2 may include a vertical cavity penetrating a top ts1 and a bottom bs1 of the PID layer PID. The via optical waveguide v3-2 may include a lower via optical waveguide v3-2a and an upper via optical waveguide v3-2b.

One side surface pf3 of the via optical waveguide v3-2 may have a shape curved in the vertical direction. In a vertical cross-section of the via optical waveguide v3-2, the one side surface pf3 may have a double elliptical structure.

As illustrated in FIG. 7D, a via optical waveguide v3-3 may include a vertical cavity penetrating a top ts1 and a bottom bs1 of the PID layer PID. One side surface pf4 of the via optical waveguide v3-3 may have a shape curved in the vertical direction. In a vertical cross-section of the via optical waveguide v3-3, the one side surface pf4 may have a single elliptical structure.

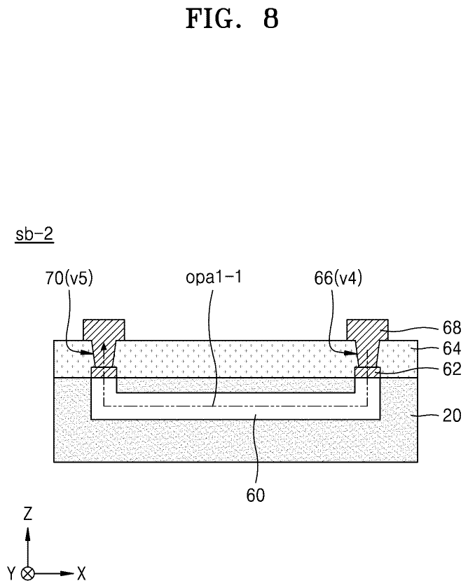

FIG. 8 is a cross-sectional view illustrating an optical PCB sb-2 according to one or more example embodiments.

Specifically, the optical PCB sb-2 may be used for the semiconductor package PK of FIG. 1. The optical PCB sb-2 may include a base layer 20, a PID layer 64, and first and second transparent pad layers 62 and 68. The optical PCB sb-2 may include a base optical waveguide 60 and first and second via optical waveguides v4 and v5.

The base layer 20 may be referred to as a base substrate. In one or more example embodiments, the base layer 20 may include flame retardant 4 (FR4) including epoxy resin and glass fiber. The base optical waveguide 60 extending in the first horizontal direction (X direction) and the vertical direction (Z direction) may be arranged in the base layer 20.

The PID layer 64 may be arranged on the base layer 20 excluding the base optical waveguide 60. The PID layer 64 may include an organic layer. In one or more example embodiments, the PID layer 64 may include a material layer including novolac resin. In one or more example embodiments, the PID layer 64 may include a material layer including polyimide (PI) resin or polybenzoxazole (PBO) resin.

The first and second via optical waveguides v4 and v5 extending in the vertical direction (Z direction) may be arranged in the PID layer 64. The first via optical waveguide v4 may be arranged on one side of the base optical waveguide 60 in connection with the base optical waveguide 60. The first via optical waveguide v4 may include a first vertical cavity penetrating the top and bottom of the PID layer 64.

The second via optical waveguide v5 may be arranged on the other side of the base optical waveguide 60 in connection with the base optical waveguide 60. The second via optical waveguide v5 may include a second vertical cavity penetrating the top and bottom of the PID layer 64. The first and second via optical waveguides v4 and v5 may be formed in the PID layer 64 by a photo process. Accordingly, the first and second via optical waveguides v4 and v5 may be easily adjusted in size and formed into various structures.

The first and second via optical waveguides v4 and v5 may be provided in the PID layer 64 to reduce light reflectance and light diffuse reflectance and to reduce optical loss. In addition, the optical PCB sb-2 may include the PID layer 64 to reduce a coefficient of thermal expansion (CTE) and to reduce the possibility of mechanical deformation due to temperature changes.

The first and second transparent pad layers 62 and 68 may be arranged on the first and second via optical waveguides v4 and v5 and the PID layer 64. An optical element or an electrical element may be mounted on the first and second transparent pad layers 62 and 68. The optical PCB sb-2 may include a first optical path opa1-1 passing through the first via optical waveguide v4, the base optical waveguide 60, and the second via optical waveguide v5. Light may be transmitted between a first light input/output unit 66(v4) and a second light input/output unit 70(v5) in the first optical path opa1-1. Light may be transmitted in the first optical path opa1-1 in the first horizontal direction (X direction) and the vertical direction (Z direction).

The optical PCB sb-2 as described above may transmit light while reducing optical loss in the first horizontal direction (X direction), the second horizontal direction (Y direction), and the vertical direction (Z direction) through the base optical waveguide 60 and the first and second via optical waveguides v4 and v5.

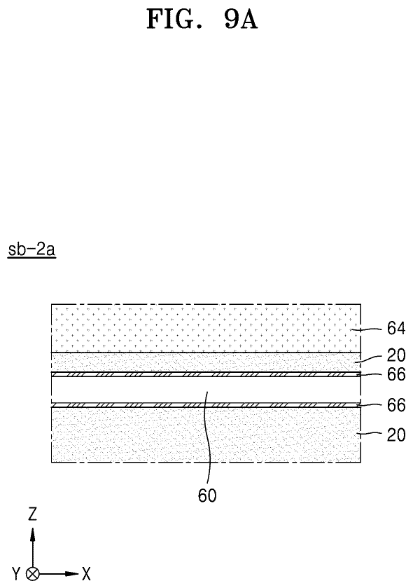

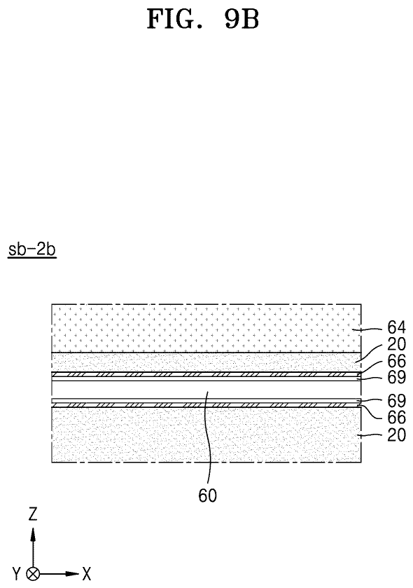

FIGS. 9A and 9B are cross-sectional views illustrating an optical PCB sb-2a according to one or more example embodiments.

Specifically, the optical PCB sb-2a may be the same as the optical PCB sb-2 of FIG. 8 except that a metal layer 66 may be further formed on one side wall of a base optical waveguide 60.

The optical PCB sb-2b may be the same as the optical PCB sb-2 of FIG. 8 except that a metal layer 66 and an anti-reflection layer 69 may be further formed on one side wall of a base optical waveguide 60. In FIGS. 9A and 9B, the same reference numerals as in FIG. 8 denote the same members. In FIGS. 9A and 9B, duplicative description previously given with reference to FIG. 8 is omitted.

In the optical PCB sb-2a, a metal layer 66 may be further formed on one side wall of the base optical waveguide 60. The metal layer 66 may be referred to as a metal seed layer. The metal layer 66 may include a metal seed of about 50 nm to about 300 nm. Because the metal layer 66 has a small surface roughness of about 50 nm to about 300 nm, reflection or scattering of an optical signal traveling through the base optical waveguide 60 may be reduced. The metal layer 66 may include a Cu layer.

In the optical PCB sb-2b, a metal layer 66 and an anti-reflection layer 69 may be further formed on one side wall of the base optical waveguide 60. The anti-reflection layer 69 may include a material layer for preventing reflection of ultraviolet rays. The anti-reflection layer 69 may be referred to as an anti-reflection coating layer. The anti-reflection layer 22 may serve to prevent reflection of the optical signal transmitted to the base optical waveguide 60.

Reflectance of the anti-reflection layer 69 with respect to ultraviolet rays may be 0.5% or less. Reflectance of the anti-reflection layer 69 with respect to ultraviolet rays may be about 0.2% to about 0.3%. In one or more example embodiments, the anti-reflection layer 69 may include titanium oxide (TiO₂), magnesium fluoride (MgF₂), or a combination thereof.

In the optical PCB sb-2b of FIG. 9B, a stacking order of the metal layer 66 and the anti-reflection layer 69 may be changed. For example, the anti-reflection layer 69 and the metal layer 66 may be sequentially formed on one side wall of the base optical waveguide 60. In addition, in the optical PCB sb-2b of FIG. 9B, the metal layer 66 may not be formed and only the anti-reflection layer 69 may be formed.

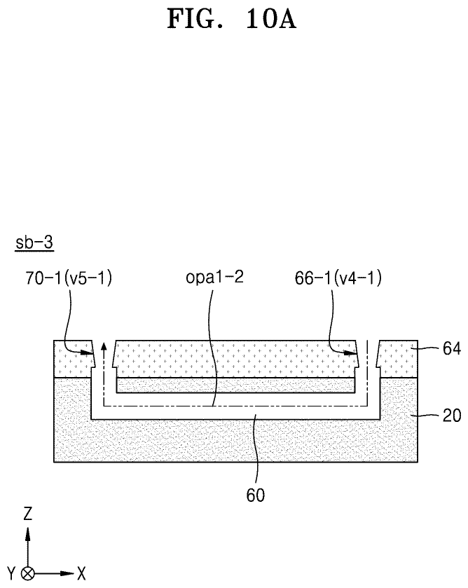

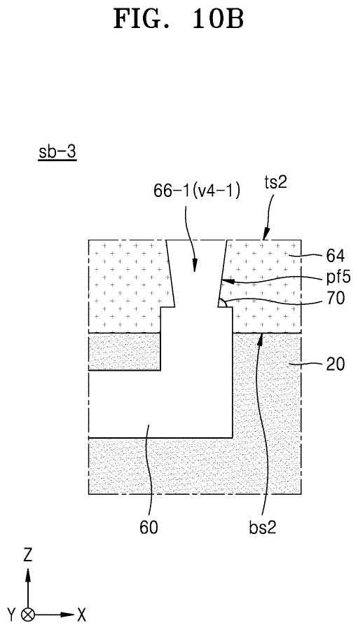

FIGS. 10A and 10B are cross-sectional views illustrating an optical PCB sb-3 according to one or more example embodiments.

Specifically, the optical PCB sb-3 may be used for the semiconductor package PK of FIG. 1. The optical PCB sb-3 may include a base layer 20 and a PID layer 64. The optical PCB sb-3 may include a base optical waveguide 60 and first and second via optical waveguides v4-1 and v5-1.

The base layer 20 may be referred to as a base substrate. In one or more example embodiments, the base layer 20 may include flame retardant 4 (FR4) including epoxy resin and glass fiber. The base optical waveguide 60 extending in the first horizontal direction (X direction) and the vertical direction (Z direction) may be arranged in the base layer 20.

The PID layer 64 may be arranged on the base layer 20 excluding the base optical waveguide 60. The PID layer 64 may include an organic layer. In one or more example embodiments, the PID layer 64 may include a material layer including novolac resin. In one or more example embodiments, the PID layer 64 may include a material layer including polyimide (PI) resin or polybenzoxazole (PBO) resin.

The first and second via optical waveguides v4-1 and v5-1 extending in the vertical direction (Z direction) may be arranged in the PID layer 64. The first via optical waveguide v4-1 may be arranged on one side of the base optical waveguide 60 in connection with the base optical waveguide 60.

The first via optical waveguide v4-1 may include a vertical cavity penetrating the top and bottom of the PID layer 64. As illustrated in FIG. 10B, the first via optical waveguide v4-1 may include a vertical cavity penetrating a top ts2 and a bottom bs2 of the PID layer 64.

One side surface pf5 of the first via optical waveguide v4-1 may have a shape inclined in a horizontal direction. The one side surface pf5 of the first via optical waveguide v4-1 may be inclined at an angle less than 90 degrees with respect to the bottom bs2 of the PID layer 64 as indicated by reference numeral 70.

The second via optical waveguide v5-1 may be arranged on the other side of the base optical waveguide 60 in connection with the base optical waveguide 60. The second via optical waveguide v5-1 may include a vertical cavity penetrating top and bottom of the PID layer 64. The second via optical waveguide v5-1 may have the same structure as the first via optical waveguide v4-1.

The first and second via optical waveguide v4-1 and v5-1 may be formed in the PID layer 64 by a photo process. Accordingly, the first and second via optical waveguides v4-1 and v5-1 may be easily adjusted in size and formed into various structures.

The first and second via optical waveguides v4-1 and v5-1 may be provided in the PID layer 64 to reduce light reflectance and light diffuse reflectance and to reduce optical loss. In addition, the optical PCB sb-3 may include the PID layer 64 to reduce a coefficient of thermal expansion (CTE) and to reduce the possibility of mechanical deformation due to temperature changes.

The optical PCB sb-3 may include a first optical path opa1-2 passing through the first via optical waveguide v4-1, the base optical waveguide 60, and the second via optical waveguide v5-1. Light may be transmitted between a first light input/output unit 66-1 and a second light input/output unit 70-1 in the first optical path opa1-2. Light may be transmitted in the first optical path opa1-2 in the first horizontal direction (X direction) and the vertical direction (Z direction).

The optical PCB sb-2 as described above may transmit light while reducing optical loss in the first horizontal direction (X direction), the second horizontal direction (Y direction), and the vertical direction (Z direction) through the base optical waveguide 60 and the first and second via optical waveguides v4-1 and v5-1.

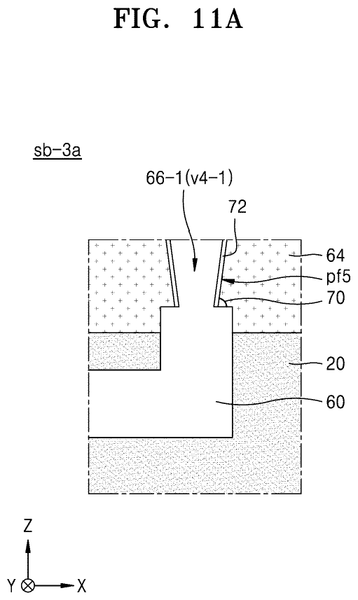

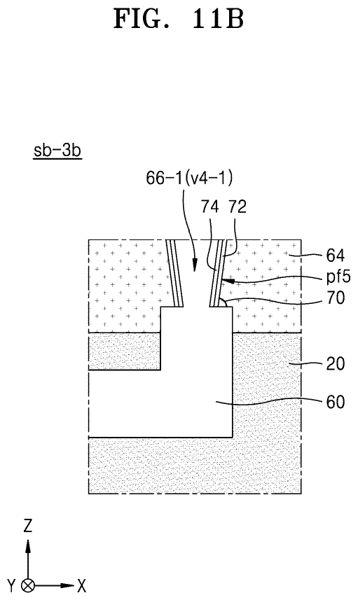

FIGS. 11A and 11B are cross-sectional views illustrating an optical PCB sb-3a according to one or more example embodiments.

Specifically, the optical PCB sb-3a may be the same as the optical PCB sb-3 of FIG. 10A except that a metal layer 72 may be further formed on one side wall of each of the first via optical waveguide v4-1 and the second via optical waveguide v5-1.

Specifically, the optical PCB sb-3b may be the same as the optical PCB sb-3 of FIG. 10A except that a metal layer 72 and an anti-reflection layer 74 may be further formed on one side wall of each of the first via optical waveguide v4-1 and the second via optical waveguide v5-1.

In FIGS. 11A and 11B, for convenience, only the first via optical waveguide v4-1 is illustrated. In FIGS. 11A and 11B, the same reference numerals as in FIG. 10A denote the same members. In FIGS. 11A and 11B, duplicative description previously given with reference to FIG. 10A is omitted.

In the optical PCB sb-3a, a metal layer 66 may be further formed on one side wall of the first via optical waveguide v4-1. The metal layer 66 may be referred to as a metal seed layer. The metal layer 66 may include a metal seed of about 50 nm to about 300 nm. Because the metal layer 66 has a small surface roughness of about 50 nm to about 300 nm, reflection or scattering of the optical signal traveling through the base optical waveguide 60 may be reduced. The metal layer 66 may include a Cu layer.

In the optical PCB sb-3b, a metal layer 72 and an anti-reflection layer 74 may be further formed on one side wall of the first via optical waveguide v4-1. The anti-reflection layer 74 may include a material layer for preventing reflection of ultraviolet rays. The anti-reflection layer 74 may be referred to as an anti-reflection coating layer. The anti-reflection layer 74 may serve to prevent reflection of the optical signal transmitted to the base optical waveguide 60.

Reflectance of the anti-reflection layer 74 with respect to ultraviolet rays may be 0.5% or less. Reflectance of the anti-reflection layer 74 with respect to ultraviolet rays may be about 0.2% to about 0.3%. In one or more example embodiments, the anti-reflection layer 74 may include titanium oxide (TiO₂), magnesium fluoride (MgF₂), or a combination thereof.

In the optical PCB sb-3b of FIG. 11B, a stacking order of the metal layer 72 and the anti-reflection layer 74 may be changed. For example, the anti-reflection layer 74 and the metal layer 72 may be sequentially formed on one side wall of the first via optical waveguide v4-1. In addition, in the optical PCB sb-3b of FIG. 11B, the metal layer 72 may not be formed and only the anti-reflection layer 74 may be formed.

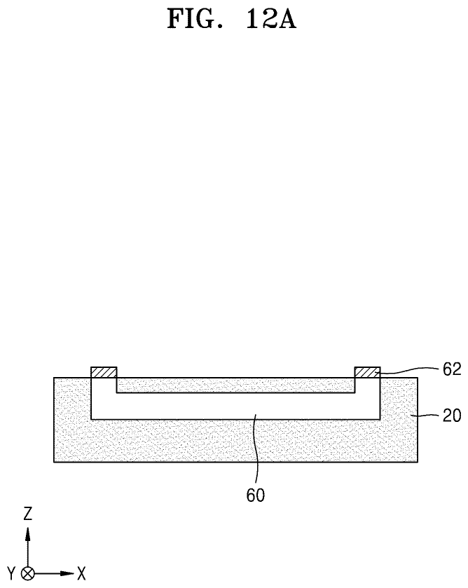

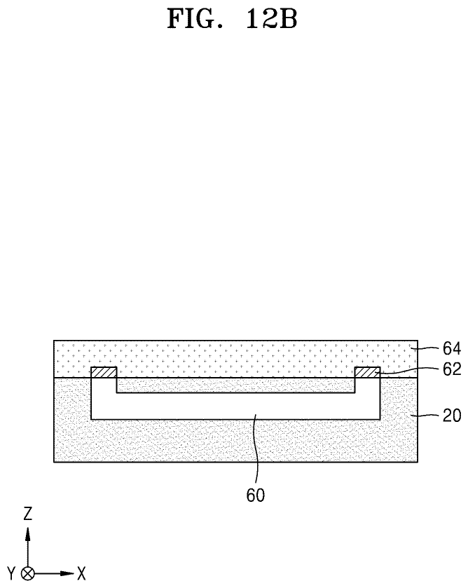

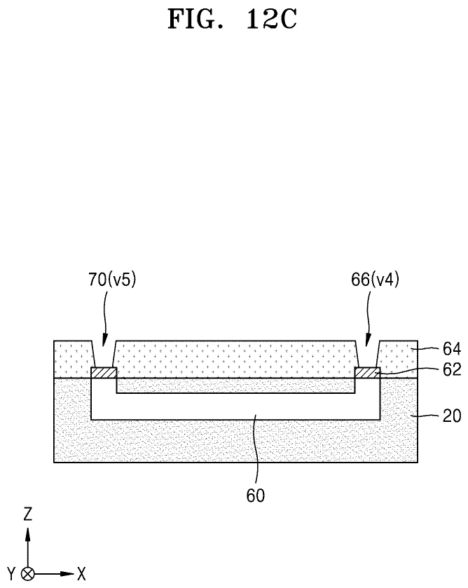

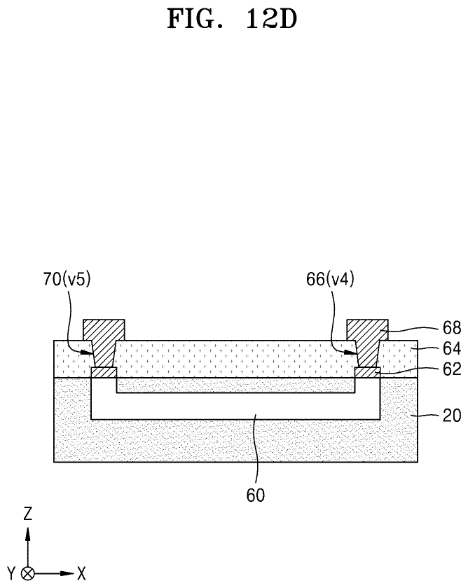

FIGS. 12A, 12B, 12C and 12D are cross-sectional views illustrating a method of manufacturing the optical PCB illustrated in FIG. 9 according to one or more example embodiments.

Specifically, in FIGS. 12A, 12B, 12C and 12D, the same reference numerals as in FIG. 9 denote the same members. In FIGS. 12A, 12B, 12C and 12D, duplicative description previously given with reference to FIG. 9 will be briefly given or omitted.

Referring to FIG. 12A, a base layer 20 may be prepared. The base layer 20 may be referred to as a base substrate. In one or more example embodiments, the base layer 20 may include flame retardant 4 (FR4) including epoxy resin and glass fiber.

The base optical waveguide 60 may be formed in the base layer 20. The base optical waveguide 60 may extend in the first horizontal direction (X direction) and the vertical direction (Z direction). The base optical waveguide 60 may be formed by a photolithography process. The first transparent pad layer 62 may be formed on the base optical waveguide 60.

Referring to FIG. 12B, the PID layer 64 may be formed on the base layer 20 and the first transparent pad layer 62. The PID layer 64 may be attached in the form of a film or may be applied in the form of a liquid and then cured. The PID layer 64 may include an organic layer. In one or more example embodiments, the PID layer 64 may include a material layer including novolac resin. In one or more example embodiments, the PID layer 64 may include a material layer including polyimide (PI) resin or polybenzoxazole (PBO) resin.

Referring to FIG. 12C, the first and second via optical waveguides v4 and v5 extending in the vertical direction (Z direction) may be formed in the PID layer 64.

The first and second via optical waveguides v4 and v5 may be formed to expose the first transparent pad layer 62. The first via optical waveguide v4 may include the first light input/output unit 66. The second via optical waveguide v5 may include a second light input/output unit 70.

The first and second via optical waveguides v4 and v5 may be formed in the PID layer 64 by a photo process. Accordingly, the first and second via optical waveguides v4 and v5 may be easily adjusted in size and formed into various structures.

Referring to FIG. 12D, the second transparent pad layer 68 may be formed on the first transparent pad layer 62 in the first and second via optical waveguides v4 and v5. The first and second transparent pad layers 62 and 68 may be formed on the first and second via optical waveguides v4 and v5 and the PID layer 64. An optical element or an electrical element may be mounted on the first and second transparent pad layers 62 and 68.

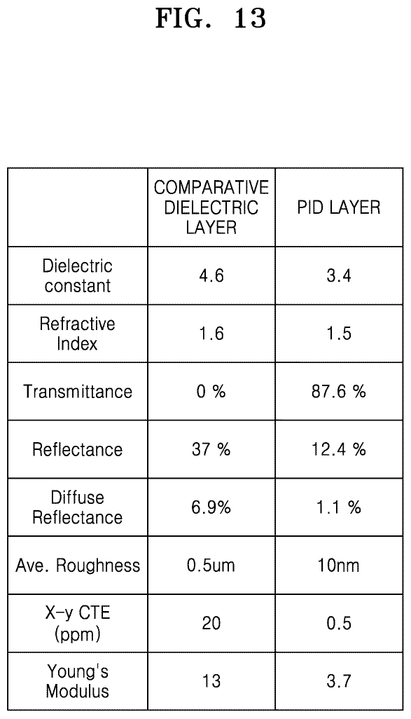

FIG. 13 is a diagram for explaining optical characteristics of a PID layer used for an optical PCB according to one or more example embodiments and a comparative dielectric layer of a comparative example.

Specifically, in FIG. 13, the optical characteristics of the PID layer (for example, 26 or 32 of FIGS. 2A and 2B) used for the optical PCB according to one or more example embodiments (for example, sb of FIGS. 2A and 2B) are compared with the optical characteristics of the comparative dielectric layer of the comparative example. The comparative dielectric layer include an Ajinomoto build-up film. The Ajinomoto build-up film may be a material layer including epoxy resin and inorganic particles.

The PID layer (for example, 26 or 32 of FIGS. 2A and 2B) used for the optical PCB according to one or more example embodiments has a lower dielectric constant or refractive index than the dielectric layer of the comparative example, which may be advantageous for high-speed optical communication.

Transmittance and reflectance are measured at an ultraviolet wavelength (302 nm). Diffuse reflectance is measured at an ultraviolet wavelength (365 nm). The PID layer used in the optical PCB according to one or more example embodiments has lower reflectance and diffuse reflectance than the dielectric layer of the comparative example so that light may be transmitted while reducing optical loss.

The PID layer used in the optical PCB according to one or more example embodiments has lower average roughness than the dielectric layer of the comparative example so that light may be transmitted while reducing optical loss.

The PID layer used in the optical PCB according to one or more example embodiments has lower CTE and Young's modulus than the dielectric layer of the comparative example so that deformation of the optical PCB may be reduced and light may be transmitted while reducing optical loss.

While one or more example embodiments have been particularly shown and described above, it will be apparent to those skilled in the art that various changes in form and details may be made therein without departing from the spirit and scope of the following claims.

What is claimed is:

1. A semiconductor package comprising:
an optical printed circuit board (PCB); and
an integrated circuit device on the optical PCB,
wherein the optical PCB comprises:
a base layer;
at least one photoimageable dielectric (PID) layer on the base layer;
a horizontal optical waveguide extending in a horizontal direction in the at least one PID layer;
a first via optical waveguide on a first side of the horizontal optical waveguide, in optical communication with the horizontal optical waveguide, and extending perpendicular to the at least one PID layer; and
a second via optical waveguide on a second side of the horizontal optical waveguide, in optical communication with the horizontal optical waveguide, and extending in a vertical direction.

2. The semiconductor package of claim 1, wherein the first via optical waveguide, the horizontal optical waveguide, and the second via optical waveguide comprise an optical path configured transmit an optical signal therethrough.

3. The semiconductor package of claim 1, wherein each of the first via optical waveguide and the second via optical waveguide comprises a vertical cavity passing through an upper portion and a lower portion of the at least one PID layer.

4. The semiconductor package of claim 1, wherein the horizontal optical waveguide comprises a horizontal cavity in the at least one PID layer.

5. The semiconductor package of claim 1, further comprising a lower metal layer contacting a bottom of the first via optical waveguide, a bottom of the horizontal optical waveguide, and a bottom of the second via optical waveguide.

6. The semiconductor package of claim 5, further comprising a lower anti-reflection layer between the lower metal layer and the base layer.

7. The semiconductor package of claim 1, further comprising an upper metal layer on the at least one PID layer.

8. The semiconductor package of claim 7, further comprising an upper anti-reflection layer on the upper metal layer.

9. The semiconductor package of claim 1, wherein, in a cross-section of the first via optical waveguide, an upper width of the first via optical waveguide is greater than a lower width of the first via optical waveguide, and one side surface of the first via optical waveguide is inclined, and
wherein, in a cross-section of the second via optical waveguide, an upper width of the second via optical waveguide is greater than a lower width of the second via optical waveguide, and one side surface of the second via optical waveguide is inclined.

10. The semiconductor package of claim 1, wherein, in a cross-section of the first via optical waveguide, one side surface of the first via optical waveguide has a single elliptical structure or a double elliptical structure, and
wherein, in a cross-section of the second via optical waveguide, one side surface of the second via optical waveguide has a single elliptical structure or a double elliptical structure.

11. A semiconductor package comprising:
an optical printed circuit board (PCB); and
an integrated circuit device on the optical PCB,
wherein the optical PCB comprises:
a base layer;
a lower photoimageable dielectric (PID) layer on the base layer;
an upper PID layer on the lower PID layer;
a horizontal optical waveguide extending in a horizontal direction in the lower PID layer;
a first via optical waveguide on a first side of the horizontal optical waveguide, in optical communication with the horizontal optical waveguide, and extending in a direction perpendicular to the lower PID layer and perpendicular to the upper PID layer; and
a second via optical waveguide on a second side of the horizontal optical waveguide, in optical communication with the horizontal optical waveguide, and extending perpendicular to the lower PID layer and perpendicular to the upper PID layer.

12. The semiconductor package of claim 11, wherein each of the first via optical waveguide and the second via optical waveguide comprises a vertical cavity penetrating a top and a bottom of the lower PID layer and penetrating a top and a bottom of the upper PID layer, and
wherein the horizontal optical waveguide comprises a horizontal cavity in the lower PID layer.

13. The semiconductor package of claim 11, further comprising:
a lower metal layer contacting a bottom of the first via optical waveguide, a bottom of the horizontal optical waveguide, and a bottom of the second via optical waveguide; and
a lower anti-reflection layer between the lower metal layer and the base layer.

14. The semiconductor package of claim 11, further comprising:
an upper metal layer arranged on the lower PID layer; and
an upper anti-reflection layer on the upper PID layer.

15. A semiconductor package comprising:
an optical printed circuit board (PCB); and
an integrated circuit device on the optical PCB,
wherein the optical PCB comprises:
a base layer;
a base optical waveguide extending in a horizontal direction and a vertical direction in the base layer;
a photoimageable dielectric (PID) layer on the base layer;
a first via optical waveguide on a first side of the base optical waveguide, in optical communication with the base optical waveguide, and extending perpendicular to the PID layer; and
a second via optical waveguide on a second side of the base optical waveguide, in optical communication with the base optical waveguide, and extending perpendicular to the PID layer.

16. The semiconductor package of claim 15, wherein each of the first via optical waveguide and the second via optical waveguide comprises a vertical cavity penetrating a top and a bottom of the PID layer, and
wherein the base optical waveguide comprises a horizontal cavity and a vertical cavity in the base layer.

17. The semiconductor package of claim 15, further comprising at least one of a metal layer and an anti-reflection layer on one side wall of the base optical waveguide.

18. The semiconductor package of claim 15, further comprising at least one of a metal layer and an anti-reflection layer on one side wall of the first via optical waveguide and on one side wall of the second via optical waveguide.

19. The semiconductor package of claim 15, further comprising transparent pad layers in the first via optical waveguide and in the second via optical waveguide.

20. The semiconductor package of claim 15, wherein, in a cross-section of the first via optical waveguide, one side surface of the first via optical waveguide is inclined, and
wherein, in a cross-section of the second via optical waveguide, one side surface of the second via optical waveguide is inclined.
